(19) United States
(12) Patent Application Publication
(10) Pub. No.: US 2010/0243422 A1
(43) Pub. Date: Sep. 30, 2010

(54) INFORMATION INPUT DEVICE

(75) Inventors: Takeshi Arihara, Kyoto City (JP); Katsumi Edo, Takatsuki City (JP)

Correspondence Address: OSHA LIANG L.L.P., TWO HOUSTON CENTER, 909 FANNIN, SUITE 3500, HOUSTON, TX, 77010, US

(73) Assignee: OMRON CORPORATION, Kyoto-shi (JP)

(21) Appl. No.: 12/709,386

(22) Filed: Feb. 19, 2010

(30) Foreign Application Priority Data
Mar. 31, 2009 (JP) 2009-086269

(51) Int. Cl. H03K 17/975

(52) U.S. Cl. 200/600

(57) ABSTRACT

An information input device includes a flexible print substrate including first, second and third installation units, first and second coupling units coupling the first installation unit with the second installation unit and the second installation unit with the third installation unit respectively, so that the first, second, and third installation units are extended along a same axis, the first, the second, and the third installation units being folded to a bellows form and integrated through the first and the second coupling units, a sensor sheet, an operation plate configured to be pushably installed by means of the sensor sheet on an upper surface of the third installation unit, a push button configured to be pushably assembled through an operation hole formed in the operation plate; and a dome-shaped movable contact arranged on the second installation unit.

### BACKGROUND OF THE INVENTION

1. Technical Field

The present invention relates to an information input device incorporated in an electronic device such as a mobile phone and a digital camera.

2. Related Art

Conventionally, an information input device incorporated in an electronic device and the like includes an electrostatic capacity sensor, disclosed in Japanese Unexamined Patent Publication No. 2003-139628, including a substrate (2), an elastic rubber plate (1) arranged above the substrate (2), and an electrode unit (C) arranged on one side of the opposing surfaces of the elastic rubber plate (1) and the substrate (2) and electrode units (Cx+), (Cx−), (Cy+), (Cy−) arranged on the other side, where the mutual distance of the electrode unit (C) and the electrode units (Cx+), (Cx−), (Cy+), (Cy−) changes by the pushing-in of the elastic rubber plate (1).

### SUMMARY

However, the output signal is merely output with the change in the electrostatic capacity converted to the change in voltage in the above information input device. Thus, when a pointing device is used, the cursor can be merely moved to a predetermined position, and cannot output a selection command. As a result, an output unit for outputting the output signal is separately required, where the problem of enlargement arises with multi-function.

One or more embodiments of the present invention provide a multi-functional small information input device.

In accordance with one aspect of the present invention, an information input device includes a flexible print substrate including first, second and third installation units; first and second coupling units coupling the first installation unit with the second installation unit and the second installation unit with the third installation unit respectively, so that the first, second, and third installation units are extended along a same axis, the first, the second, and the third installation units being folded to a bellows form and integrated through the first and the second coupling units; a sensor sheet; an operation plate configured to be pushably installed by means of the sensor sheet on an upper surface of the third installation unit; a push button configured to be pushably assembled through an operation hole formed in the operation plate; and a dome-shaped movable contact arranged on the second installation unit, wherein an electrostatic capacity of the sensor sheet is changed and an output signal is output when the operation plate assembled to the third installation unit is pushed down thereby elastically compressing the sensor sheet, and the dome-shaped movable contact arranged on the second installation unit is driven through an operation hole formed in the third installation unit when the push button is pushed down.

According to one or more embodiments of the present invention, operation is not only carried out with the operation plate, and the external circuit can be turned ON, OFF by driving the dome-shaped movable contact with the push button, and thus a multi-function information input device can be obtained.

An information input device with small bottom area is obtained as the first, the second, and the third installation units of the FPC are three-folded through the first and the second coupling units.

In the above aspect, an annular rib for preventing false operation of the push button may be arranged in a projecting manner on the upper surface of the operation plate.

According to one or more embodiments of the present invention, an information input device with few false operation and high operability is obtained although it is multifunctional.

In the above aspect, a base plate may be stacked and integrated between the first installation unit and the second installation unit.

According to one or more embodiments of the present invention, the breakage of solder can be prevented and the durability can be enhanced as the base plate enhances the rigidity of the entire device and the bend of the FPC that occurs by the operation on the operation plate and the push button is suppressed.

In the above aspect, an electronic component such as an IC may be arranged on an exposed surface of the first installation unit.

According to one or more embodiments of the present invention, the space can be saved by arranging the IC and the like on the exposed surface of the first installation unit, and hence an information input device having small bottom area can be obtained. Furthermore, since all electronic components such as the IC are mounted on the same flexible print substrate, an information input device with less variation of the electrostatic capacity than when connecting the IC and the like with the connector and the like can be obtained.

In the above aspect, a spacer for protecting the electronic component such as the IC may be stacked and integrated on the exposed surface of the first installation unit.

According to one or more embodiments of the present invention, the electronic component such as the IC can be protected, and furthermore, the bottom surface of the device can be formed flat, whereby the assembly to the electronic device is facilitated.

### BRIEF DESCRIPTION OF THE DRAWINGS

FIGS. 1A and 1B are a plan view and a bottom view of an information input device according to one or more embodiments of the present invention;

FIGS. 2A and 2B are perspective views of the information input device shown in FIGS. 1A and 1B seen from different angles;

FIGS. 3A and 3B are perspective views showing a state in which the information input device shown in FIGS. 2A and 2B is developed;

FIG. 4 is an exploded perspective view of FIG. 3A;

FIG. 5 is an exploded perspective view of FIG. 3B;

FIG. 6 is an enlarged cross-sectional view of a state in which the information input device shown in FIGS. 1A and 1B is developed; and

FIG. 7 is an enlarged cross-sectional view of a state in which the information input device shown in FIGS. 1A and 1B is assembled.

### DETAILED DESCRIPTION

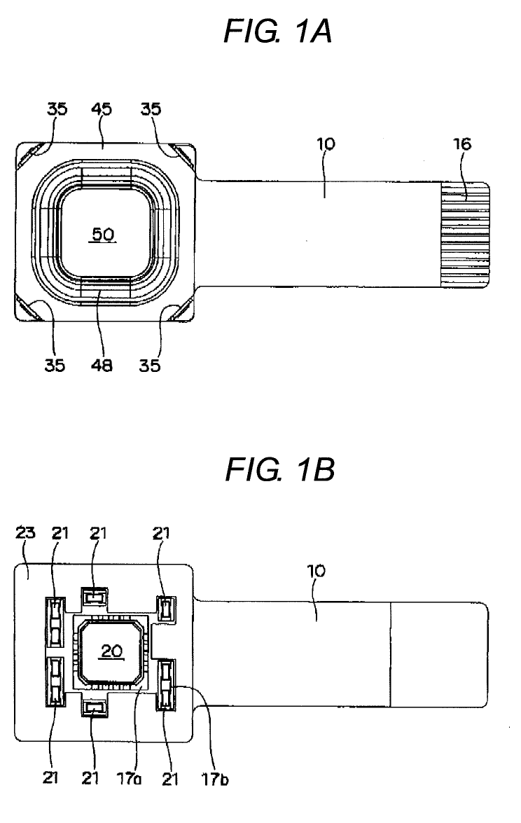

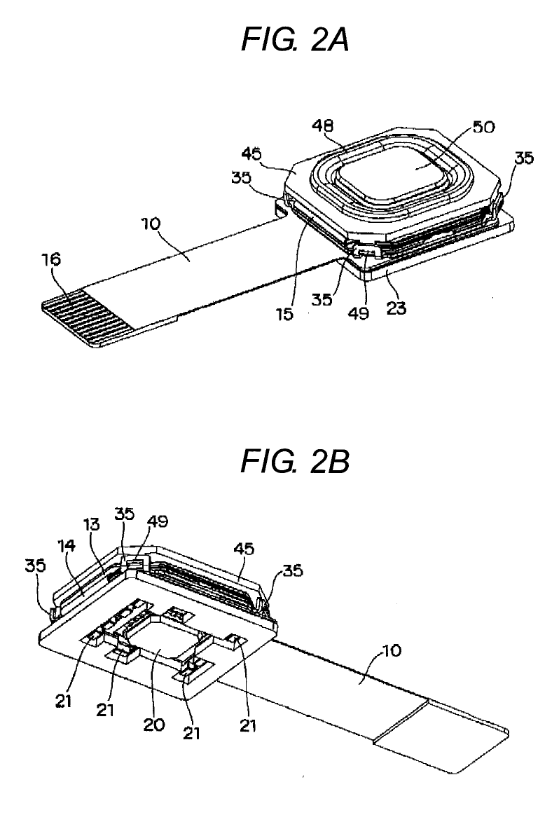

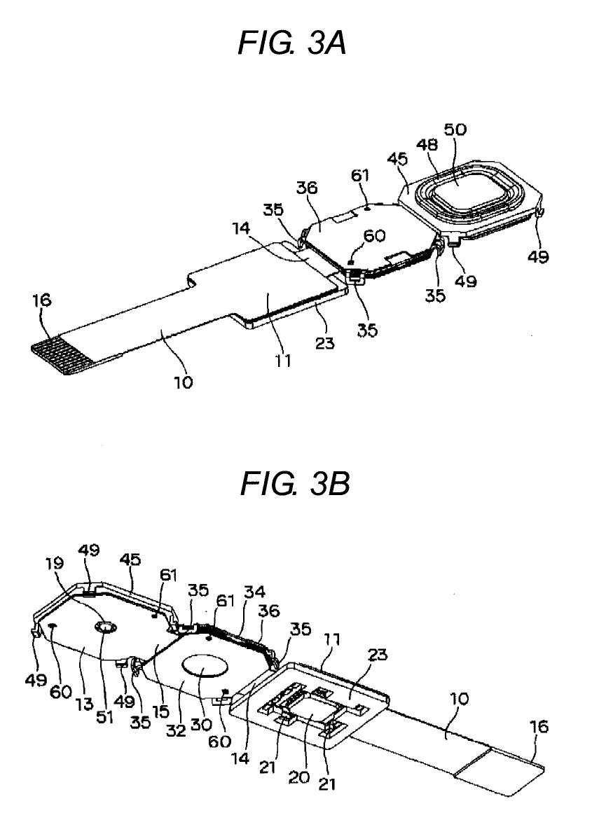

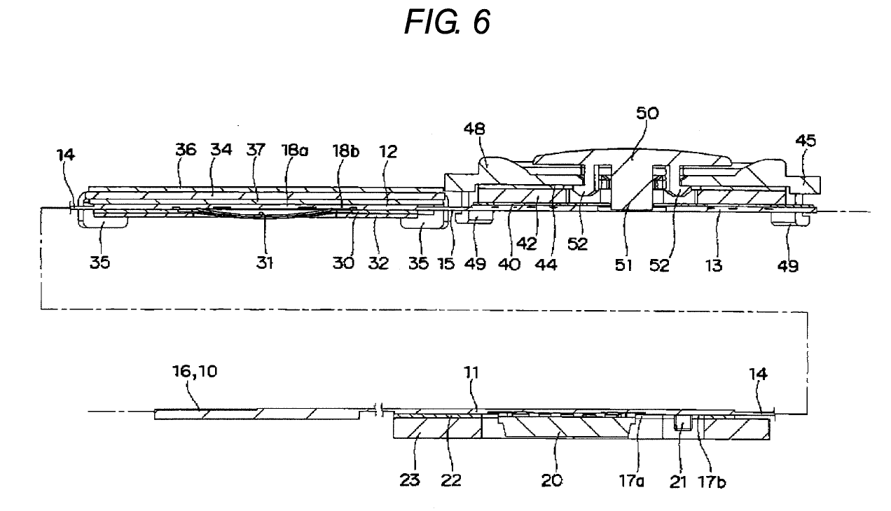

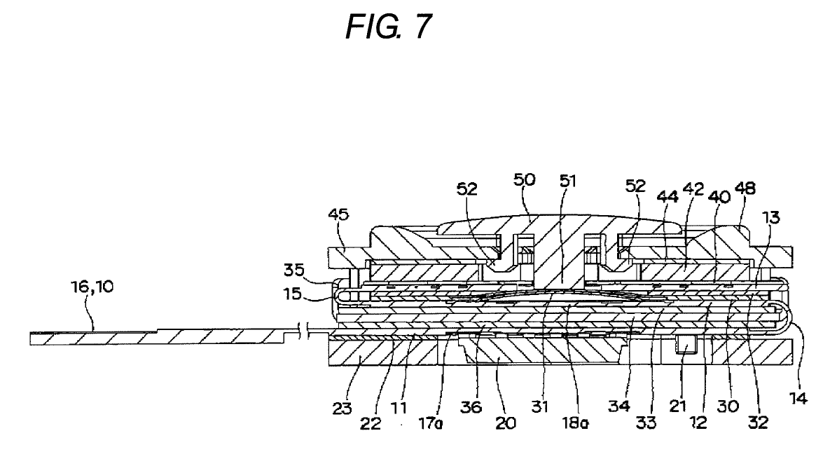

Hereinafter, embodiments of the information input device according to the present invention will be described with reference to the accompanied drawings FIGS. 1 to 7.

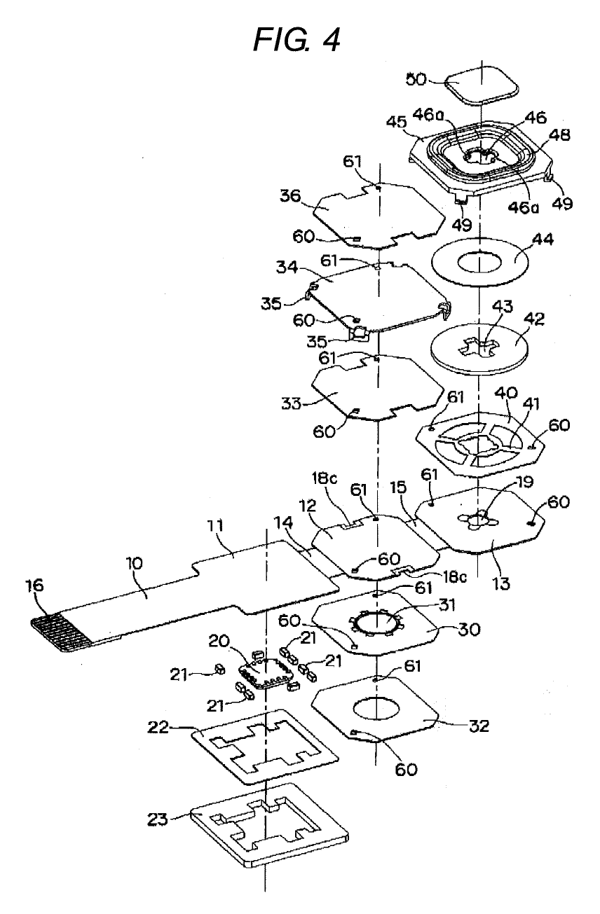

As shown in FIG. 4, the information input device according to one or more embodiments of the present invention is roughly configured by a flexible print substrate 10 (hereinafter referred to as “FPC”), a spacer 23, a dome-shaped sheet 30, a base plate 34, an insulating sheet 40, a sensor sheet 42, an operation plate 45, and a central push button 50.

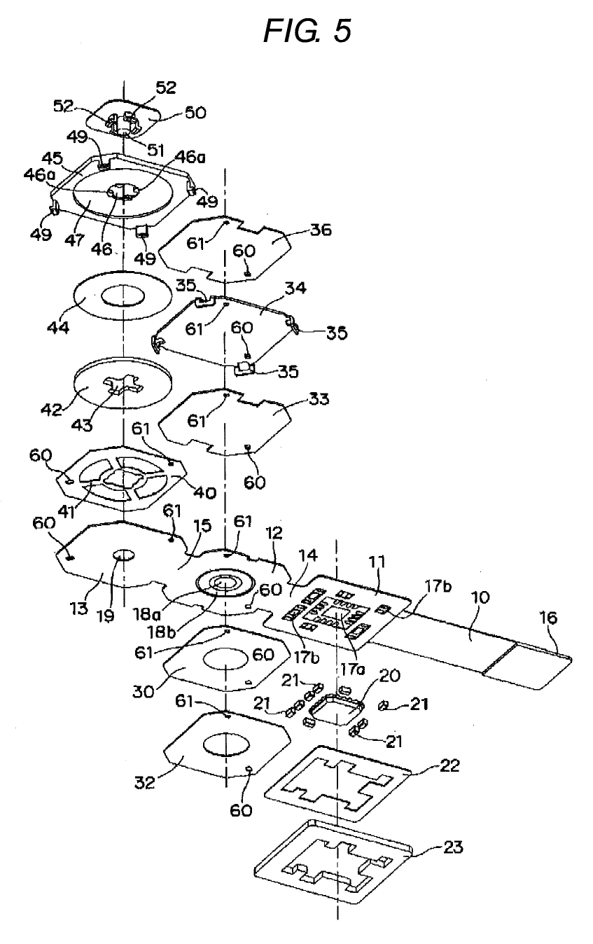

The FPC 10 has three units or first, second, and third installation units 11, 12, 13 extending on the same axial center so as to be connected through first and second coupling units 14, 15, where a connection unit 16 is arranged at one end thereof. As shown in FIG. 5, a first connection receiving portion 17a, where an IC 20 or a control circuit can be mounted, is arranged at the lower surface of the first installation unit 11, and a second connection receiving portion 17b, where an electronic component 21 such as a capacitor can be mounted, is arranged at the periphery (see FIG. 5). Concentric fixed contacts 18a, 18b are arranged at the central part of the back surface of the second installation unit 12, where the edge on both sides is cut out to form an earth connecting portion 18c for connecting a base plate 34, to be hereinafter described. An operation hole 19 is formed at the center of the third installation unit 13.

The spacer 23 is attached to the lower surface of the first installation unit 11 by way of a double-sided tape 22 to protect the IC 20 and the electronic component 21.

The second installation unit 12 has a dome-shaped sheet 30, which is adhered and integrated with the dome-shaped movable contact 31 at the middle, adhered and integrated at the middle of the lower surface, and has an annular double-sided tape 32 also serving as a spacer adhered and integrated to the lower surface of the dome-shaped sheet 30.

The base plate 34 is adhered and integrated to the upper surface of the second installation unit 12 through a double-sided tape 33, and is connected to the earth connecting portion 18c. The base plate 34 has a planar shape capable of converting the second installation unit 12, where an engagement receiving portion 35 is bent and raised at the corner. The base plate 34 also has a double-sided tape 36 adhered and integrated to the upper surface.

The third installation unit 13 has the insulating sheet 40 including a portioning portion 41 adhered and integrated to the upper surface, and is mounted with the sensor sheet 42. A substantially cross-shaped operation hole 43 is formed at the central part of the sensor sheet 42, and an operation plate 45 is adhered and integrated to the upper surface by way of a ring-shaped double-sided tape 44.

The operation plate 45 is square in plane so as to be able to cover the third installation unit 13, and includes an operation hole 46 at the central part thereof. A positioning recess 47 is formed at the periphery of the lower surface side of the operation hole 46, and a false operation preventing annular rib 48 (see FIG. 4) is arranged in a projecting manner at the periphery of the upper surface side. The operation plate 45 also has an elastic nail 49 arranged in a manner projecting to the lower side at the corner. A rotation-preventing projection 46a is formed at the inner peripheral surface of the operation hole 46.

The operation plate 45 has the central push button 50 assembled to the operation hole 46. The central push button 50 includes a slip-out preventing nail 52 at the base part of the operation projection 51 arranged in a projecting manner at the center of the lower surface.

The assembly method of the information input device including the above-described components will be described.

First, the IC20 is mounted on the first connection receiving portion 17a arranged at the lower surface of the first installation unit 11, and the electronic component 21 is mounted on the second connection receiving portion 17b. Furthermore, the spacer 23 is adhered and integrated to the lower surface of the first installation unit 11 by way of the double-sided tape 22.

The dome-shaped sheet 30 is then adhered and integrated to the lower surface of the second installation unit 12, and the annular double-sided tape 32 is adhered and integrated to the dome-shaped sheet 30.

The base plate 34 is fixed to the upper surface of the second installation unit 12 by way of the double-sided tape 33 and connected to the earth connecting portion 18c, and the double-sided tape 36 is adhered and integrated to the upper surface of the base plate 34.

The insulating sheet 40 is adhered and integrated to the upper surface of the third installation unit 13, and the sensor sheet 42 is adhered and integrated to the positioning recess 47 of the operation plate by way of the double-sided tape 44. The operation plate 45 is then mounted on the insulating sheet 40 and the operation projection 51 of the central push button 50 is pushed into the operation hole 46 of the operation plate 45, so that the slip-out preventing nail 52 engages to the opening edge of the operation hole 46 and prevented from slipping out.

The first coupling unit 14 of the FPC 10 is bent, and the first installation unit 11 and the second installation unit 12 are adhered and integrated by way of the double-sided tape 36. The second coupling unit 15 is then bent, so that the elastic nail 49 of the operation plate 45 engages the engagement receiving portion 35 of the base plate 34 and is adhered and integrated by way of the double-sided tape 32. The operation projection 51 of the central push button 50 then is able to push the dome-shaped movable contact 31 of the dome-shaped sheet 30.

To carry out an accurate assembly task, positioning is obviously performed through a positioning pin (not shown) to the jig holes 60, 61 formed in each member.

The operation method when the information input device is applied to the mobile phone (not shown) will now be described.

First, a specific region of the sensor sheet 42 is elastically compressed by pushing a predetermined position of the operation plate 45, and the change in electrostatic capacity generated thereby is converted to voltage, and the output signal is output. The pushing force is resolved and the movement of the cursor is stopped after the cursor of the monitor (not shown) is moved to a predetermined position based on the output signal. Thereafter, the central push button 50 is pushed down, so that the operation projection 51 pushes down and inverts the dome-shaped movable contact 31, and the dome-shaped movable contact 31 conducts the fixed contacts 18a, 18b and outputs an instruction signal. Thereafter, similar operation is repeatedly carried out.

According to one or more embodiments of the present invention, not only the IC 20 and the electronic component 21, but the dome-shaped movable contact 31, the sensor sheet 42, and the like can also be mounted and connected to the same FPC 10, and thus an information input device in which the variation of the electrostatic capacity is small compared to when connecting using a connector and the like can be obtained.

The FPC 10 is not necessarily limited to that extending on the same line, and may have a bent planar shape.

The information input device according to one or more embodiments of the present invention is not only applicable to the mobile phone, but is also obviously applicable to other electronic devices such as audio device.

1. An information input device comprising:
a flexible print substrate, comprising first, second and third installation units;
first and second coupling units coupling the first installation unit with the second installation unit and the second installation unit with the third installation unit respectively, so that the first, second, and third installation units are extended along a same axis, the first, the second, and the third installation units being folded to a bellows form and integrated through the first and the second coupling units;
a sensor sheet;
an operation plate configured to be pushably installed by means of the sensor sheet on an upper surface of the third installation unit;
a push button configured to be pushably assembled through an operation hole formed in the operation plate; and
a dome-shaped movable contact arranged on the second installation unit, wherein
an electrostatic capacity of the sensor sheet is changed and an output signal is output when the operation plate assembled to the third installation unit is pushed down thereby elastically compressing the sensor sheet, and
the dome-shaped movable contact arranged on the second installation unit is driven through an operation hole formed in the third installation unit when the push button is pushed down.

2. The information input device according to claim 1, wherein the operation plate comprises an annular rib arranged in a projecting manner on an upper surface of the operation plate.

3. The information input device according to claim 1, further comprising a base plate stacked and integrated between the first installation unit and the second installation unit.

4. The information input device according to claim 1, further comprising an electronic component arranged on an exposed surface of the first installation unit.

5. The information input device according to claim 4, further comprising a spacer stacked and integrated on the exposed surface of the first installation unit.

6. The information input device according to claim 2, further comprising a base plate stacked and integrated between the first installation unit and the second installation unit.

7. The information input device according to any claim 2, further comprising an electronic component arranged on an exposed surface of the first installation unit.

8. The information input device according to any claim 3, further comprising an electronic component arranged on an exposed surface of the first installation unit.
